(19) United States
(12) Patent Application Publication
(10) Pub. No.: US 2018/0327887 A1
(43) Pub. Date: Nov. 15, 2018

(54) REFRACTORY METAL ALLOY TARGETS FOR PHYSICAL VAPOR DEPOSITION

(71) Applicant: Intel Corporation, Santa Clara, CA (US)

(72) Inventors: Christopher J. WIEGAND, Portland, OR (US); Philip YASHAR, Portland, OR (US); Anurag CHAUDHRY, Sunnyvale, CA (US)

(73) Assignee: Intel Corporation, Santa Clara, CA (US)

(21) Appl. No.: 15/777,502

(22) PCT Filed: Dec. 18, 2015
(86) PCT No.: PCT/US15/66645

§ 371 Date: May 18, 2018

(51) Int. Cl. C22C 27/04; C23C 14/34; C23C 14/56; H01J 37/34; C22C 1/04

(52) U.S. Cl. CPC C22C 27/04; C23C 14/3414; C22C 1/045; H01J 37/3405; H01J 37/3426; C23C 14/564

(57) ABSTRACT

Refractory metal alloy targets for reducing particles in physical vapor deposition processing and refractory metal-based layer for integrated circuit applications (for example, crystallization barrier layers in non-volatile memory devices) are disclosed herein. An exemplary method for reducing particles in a PVD chamber include positioning a refractory metal alloy target in the PVD chamber, positioning a substrate in the PVD chamber a distance from the refractory metal alloy target, and sputtering material from the refractory metal alloy target to form a refractory metal-based layer over the substrate. The refractory metal alloy target includes a refractory metal (for example, tungsten or molybdenum) alloyed with a body-centered cubic (BCC) metal (for example, niobium, tantalum, vanadium, or a combination thereof). The BCC metal has a Young's modulus lower than a Young's modulus of the refractory metal.

### TECHNICAL FIELD

This disclosure relates in general to the field of integrated circuit and integrated circuit manufacturing, and more particularly, to physical vapor deposition targets and/or physical vapor deposition processes for minimizing particle contamination.

### BACKGROUND

Physical vapor deposition (PVD) is often used in integrated circuit manufacturing for forming material layers. An exemplary PVD process includes sputter deposition, which involves removing material (for example, ejecting target atoms) from a target onto a substrate to form a material layer. Certain target materials, such as refractory metals, present significant barriers to minimizing particle contamination during PVD processing, despite exhibiting desirable properties for integrated circuit applications.

### BRIEF DESCRIPTION OF THE DRAWINGS

Embodiments of the present disclosure are illustrated by way of example, and not by way of limitation, and can be more fully understood with reference to the following detailed description when considered in connection with the figures in which:

FIG. 1 illustrates a schematic block diagram of a physical vapor deposition chamber used for processing a wafer according to various aspects of the present disclosure;

FIG. 2 illustrates a flow chart of a method for reducing particles in a physical vapor deposition chamber according to various aspects of the present disclosure;

FIG. 3 illustrates a flow chart of a method for manufacturing an integrated circuit device according to various aspects of the present disclosure;

FIG. 4 illustrates a schematic cross-sectional view of an integrated circuit device according to various aspects of the present disclosure;

FIG. 5 illustrates a cross-sectional view of an exemplary material layer stack that can be implemented in a spin transfer torque magnetic random-access memory (STT-MRAM) device according to various aspects of the present disclosure;

FIG. 6 illustrates a schematic diagram of an exemplary spin transfer torque memory bit cell according to various aspects of the present disclosure;

FIG. 7 illustrates a cross-sectional view of an exemplary interposer according to various aspects of the present disclosure; and

FIG. 8 illustrates a schematic block diagram of an exemplary computing device according to various aspects of the present disclosure.

### DETAILED DESCRIPTION

Described herein are refractory metal alloy targets and associated physical vapor deposition processes for reducing flaking (and thus particle contamination), along with refractory metal-based layers for integrated circuit applications that are formed using the refractory metal alloy targets and associated physical vapor deposition processes.

The present disclosure sets forth numerous specific details, however, it will be apparent to one skilled in the art, that aspects of the present disclosure may be practiced without these specific details. In some instances, well-known methods and devices are depicted in block diagram form, rather than in detail, to avoid obscuring aspects of the present disclosure. Reference throughout this specification to “an embodiment”, “in one embodiment”, “some embodiments”, or “various embodiments” means that a particular feature, structure, function, or characteristic described in connection with the embodiment is included in at least one embodiment. Thus, such references are not necessarily referring to the same embodiment. Furthermore, the particular features, structures, functions, or characteristics may be combined in any suitable manner in one or more embodiments. For example, a first embodiment may be combined with a second embodiment anywhere the two embodiments are not specified to be mutually exclusive. Further, though various operations may be described as multiple discrete actions or operations in a manner that is most helpful in understanding the claimed subject matter, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

The terms “coupled” and “connected,” along with their derivatives, are used herein to describe structural relationships between components. It should be understood that these terms are not intended as synonyms for each other. Rather, in some embodiments, “connected” may be used to indicate that two or more elements are in direct physical or electrical contact with each other. In some embodiments, “coupled” may be used to indicate that two or more elements are in either direct or indirect (with other intervening elements between them) physical or electrical contact with each other, and/or that the two or more elements cooperate or interact with each other (for example, as in a cause an effect relationship).

The terms “over,” “under,” “between,” and “on” as used herein refer to a relative position of one material layer or component with respect to other material layers or components. For example, one layer disposed over (above) or under (below) another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

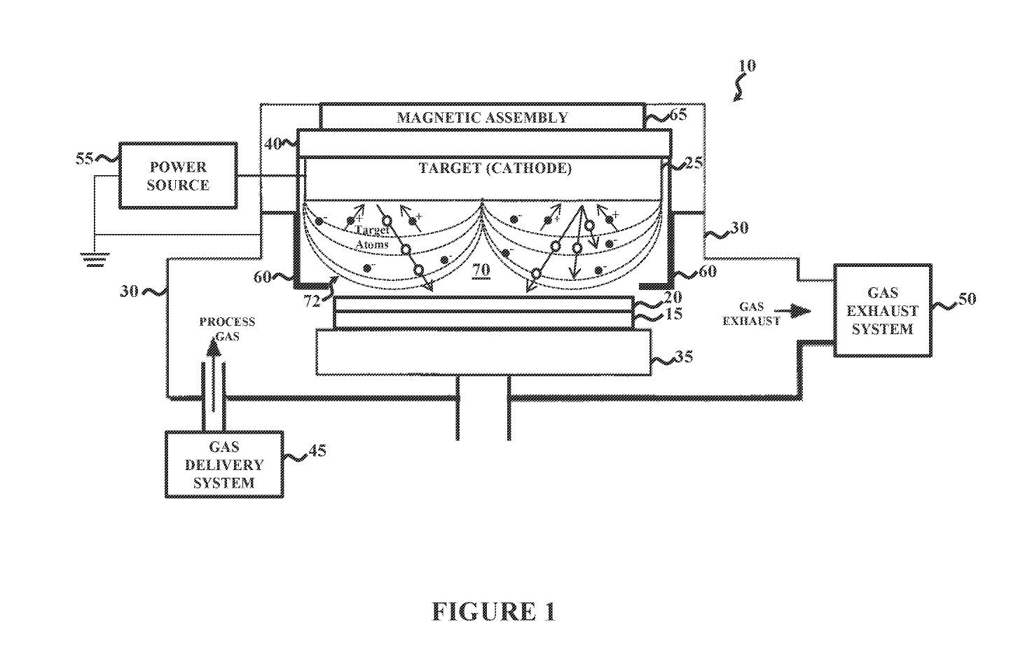

FIG. 1 illustrates a schematic block diagram of a physical vapor deposition (PVD) chamber 10 used for processing a substrate (wafer) 15 according to various aspects of the present disclosure. PVD chamber 10 performs a PVD process to form a material layer 20 over substrate 15. PVD process generally refers to depositing a material layer of atoms and/or molecules from a vapor phase onto substrate 15. In the depicted embodiment, PVD chamber 10 performs a sputter deposition process, where PVD chamber 10 sputter deposits material layer 20 over substrate 15. The sputter deposition process involves removing material (for example, ejecting target atoms) from a target 25 to form material layer 20 over substrate 15. Substrate (wafer) 15 generally includes any base material structure that serves as a foundation from which and/or upon which an integrated circuit device/component, semiconductor device/component, electronic device/component, and/or other type of device/component can be manufactured. In some implementations, substrate 15 is a semiconductor substrate (in some embodiments, patterned with a resist layer and/or a hard mask layer) used for fabricating an integrated circuit device or a quartz substrate used for fabricating a lithography mask. Substrate 15 may have undergone previous processing, such that substrate 15 includes various material layers and/or various device features formed therein and/or thereon.

PVD chamber 10 includes a chamber enclosure wall 30, a substrate support 35, a target support 40, a gas delivery system 45, a gas exhaust system 50, a power source 55, and a shield 60. PVD chamber 10 can be configured for direct current (DC) sputtering and/or radio frequency (RF) sputtering. In the depicted embodiment, PVD chamber 10 is configured for magnetron sputtering, and PVD chamber 10 includes a magnetic assembly 65. The present disclosure contemplates any modification to the configuration of PVD chamber 10, including eliminating magnetic assembly 65 and/or other PVD chamber components, to achieve the PVD processes as described herein. Further, though the depicted embodiment orients substrate 15 at a bottom portion of chamber enclosure 30 and target 25 at a top portion of chamber enclosure 30, the present disclosure contemplates other configurations of PVD chamber 10, including configurations that orient substrate 15 at a top portion of chamber 30 and target 25 at a bottom portion of chamber enclosure 30.

During PVD processing, target 25 is positioned on target support 40 in PVD chamber 10, and substrate 15 is positioned on substrate support 35 in PVD chamber 10. Target 25 is spaced any suitable distance from substrate 15. Gas delivery system 45 supplies a process gas into PVD chamber 10 through a gas inlet. For example, gas delivery system 45 supplies a non-reactive (inert) gas, such as argon-containing gas and/or xenon-containing gas, via the gas inlet into PVD chamber 10. The inert gas can serve as a gas source for plasma ions that bombard target 25, ejecting material (for example, target atoms) from target 25 onto substrate 15 to form material layer 20. In some embodiments, gas delivery system 45 also supplies a reactive gas, such as nitrogen-containing gas and/or oxygen-containing gas, via the gas inlet into PVD chamber 10. The reactive gas can serve as a gas source for reacting with material from target 25 to form material layer 20. Gas exhaust system 50 maintains a chamber pressure in PVD chamber 10. For example, gas exhaust system 50 can set a chamber pressure to sub-atmospheric levels to achieve a vacuum environment in PVD chamber 10 during processing. Gas exhaust system 50 can also remove exhaust gas (which can include spent process gas and/or byproducts) from PVD chamber 10 before, during, and/or after PVD processing.

Power source 55 supplies power to PVD chamber 10 to create an electric field in PVD chamber 10, which generates and maintains a plasma in a process area 70 (a plasma zone) in PVD chamber 10. In the depicted embodiment, process area 70 can be defined by substrate 15, target 25, and shield 60. Power source 55 is, for example, a DC power source, an RF power source, or a combination thereof. In some embodiments, PVD chamber 10 generates plasma in process area 70 by electrically biasing target 25 (for example, by applying a negative voltage via an electrical connection to target 25) while grounding chamber enclosure wall 30, substrate support 35, and shield 60 (for example, by maintaining at a ground potential via an electrical connection to chamber enclosure wall 30, substrate support 35, and/or shield 60). The electric field ionizes inert gas molecules (such as argon gas molecules), generating a plasma in process area 70 that includes the process gas molecules (which can include inert gas molecules and/or reactive gas molecules), positively charged ions (+), free electrons (-), and any sputtered target material. The positively charged ions (such as positively charged argon ions) bombard target 25 to sputter target material (such as target atoms and/or molecules) from target 25 to form material layer 20 over substrate 15. For example, target atoms sputtering from target 25 can escape the plasma and deposit over substrate 15. In some embodiments, sputtered target material can react with reactive gas ions (such as nitrogen ions when nitrogen-containing gas is supplied in PVD chamber 10) to form material layer 20. Magnetic assembly 65 generates a magnetic field 72 that confines the plasma along force lines of magnetic field 72, enhancing bombardment of ions on target 25 and/or increasing plasma density adjacent target 25 (for example, by confining free electrons near a sputtering surface of target 25).

During PVD processing, shield 60 (typically made from aluminum or stainless steel) prevents contamination of PVD chamber 10 by protecting chamber enclosure wall 30 and/or other features/components of PVD chamber 10 from excess material sputtered from target 25. Over time, excess material adhering to shield 60 accumulates and eventually flakes from shield 60, resulting in particles contaminating PVD chamber 10. Flaking can cause particle defects to form on substrate 15 and/or material layer 20, which can cause damage to substrate 15 and/or material layer 20, in some situations, significant enough to discard substrate 15. Certain target materials present significant barriers to minimizing particle contamination, despite exhibiting desirable properties for integrated circuit applications. For example, since refractory metals generally exhibit extraordinary heat resistance (typically having a melting point above 2000° C.) and wear resistance, refractory metals are well suited for barrier (liner) layers, conducting layers (such as gate electrodes in gate stacks and/or electrodes in capacitors), and/or hard mask layers in integrated circuit devices and/or integrated circuit device manufacturing. Exemplary refractory metals include tungsten (W), molybdenum (Mo), niobium (Nb), tantalum (Ta), and rhenium (Re). However, refractory metals, particularly tungsten and molybdenum, exhibit excessive flaking from shield 60 during PVD processing.

Excessive flaking occurs for various reasons. For example, since a refractory metal layer adhering to shield 60 typically exhibits a brittle (rigid) nature that does not yield well to thermal expansion/contraction, and a large difference in thermal expansion exists between the adhering refractory metal layer and shield 60, significant stresses develop in the adhering refractory metal layer as shield 60 heats and cools, causing the adhering refractory metal layer to delaminate easily from shield 60 and flake particles into PVD chamber 10 and/or onto substrate 15 during processing. One solution for minimizing stresses induced in the adhering refractory metal layer during thermal cycling is to keep shield 60 at a constant temperature. While maintaining a temperature of shield 60 reduces particle defects, such solution still proves inadequate for completely eliminating flaking of refractory metals from shield 60, particularly flaking of tungsten and molybdenum, because it fails to address stresses induced in the adhering refractory metal layer from the PVD process itself (such as from high energy imparted to the adhering refractory metal layer from sputtered refractory metal atoms during the PVD process). Further, given that refractory metals (particularly tungsten and molybdenum) have an exceedingly large Young's modulus, the refractory metal layer adhering to shield 60 is typically extremely stiff, preventing the adhering refractory metal layer from deforming as stress builds therein during PVD processing.

The present disclosure proposes refractory metal alloy targets for use in PVD processing that significantly reduce particle contamination in PVD chamber 10, and in some implementations, eliminate flaking of refractory metals (particularly tungsten-based metals and molybdenum-based metals) from shield 60 into PVD chamber 10 and/or onto substrate 15. Refractory metal alloy targets disclosed herein enable sputter deposition of refractory metal-based layers, particularly tungsten-based metal layers and molybdenum-based metal layers, with no particle defect issues, achieving high wafer yield for integrated circuit applications. To achieve such benefits (and/or other benefits not explicitly outlined herein), the present disclosure proposes refractory metal alloy targets that are softer than pure refractory metal targets, softening any refractory metal-based layer formed from the refractory metal alloy targets enough to withstand stresses induced during PVD processing (including, but not limited to, stresses induced by thermal expansion/contraction of the refractory metal-based layer adhering to shield 60 and/or formed over substrate 15 and/or stresses induced in the refractory metal-based layer from PVD processing). A softer refractory metal-based layer can handle such stresses without delaminating and/or cracking, reducing and even eliminating flaking of refractory metal particles into PVD chamber 10 and/or onto substrate 15 during PVD processing.

Various characteristics of metals are considered to identify suitable metals for alloying with a refractory metal to achieve refractory metal alloy targets and/or refractory metal-based layers that exhibit minimal to no flaking during PVD processing, such as a miscibility of the metal with the refractory metal, a lattice parameter of the metal, a Young's modulus (E_{Y}) of the metal, a resistivity of the metal, a thermal expansion coefficient of the metal, other suitable characteristic, or a combination thereof. Any metal alloyed with the refractory metal is completely miscible with the refractory metal, ensuring that the refractory metal alloyed with the metal forms a solid solution without segregating into various intermetallic phases within a resulting metal matrix (and thus avoiding intermetallic compound formation). Further, when alloying the refractory metal with a metal to form a refractory metal alloy, a Young's modulus of the refractory metal alloy will have a Young's modulus that is a weighted average of the individual Young's modulus of the refractory metal and the alloying metal. Young's modulus (also referred to as an elastic modulus) generally defines a relationship between stress and strain in a material. Accordingly, to ensure that any refractory metal-based layer fabricated from the refractory metal alloy target is soft enough to withstand the stresses described herein, any metal alloyed with the refractory metal has a Young's modulus lower than a Young's modulus of the refractory metal. Lowering the Young's modulus of the refractory metal alloy (and thus of any refractory metal-based layer fabricated therefrom) reduces susceptibility of any refractory metal-based layer adhering to shield 60 to flaking. Reducing susceptibility of excess materials on shield 60 to flaking allows loading of greater amounts of the excess materials (here, refractory metal-based material) on shield 60, thus improving (for example, increasing) time between maintenance activities for PVD chamber 10. For example, PVD chamber 10 typically remains available for manufacturing until flaking begins from shield 60, at which time, PVD chamber 10 is taken out of production for maintenance, such as to replace and/or clean shield 60. Since excess refractory metal-based material adhering to shield 60 is less likely to flake, PVD chamber 10 can remain available longer for manufacturing activities.

In FIG. 1, target 25 is a refractory metal alloy target. Refractory metal alloy target includes a refractory metal alloyed with a body-centered cubic (BCC) metal. As noted above, exemplary refractory metals include tungsten, molybdenum, niobium, tantalum, and rhenium. A Young's modulus of the BCC metal is lower than a Young's modulus of the refractory metal, and a Young's modulus of the refractory metal alloy target is lower than a Young's modulus of the refractory metal. BCC metal generally refers to any metal having a body-centered cubic structure, where the BCC structure includes BCC unit cells and a BCC unit cell is a cube having an atom at each corner of the cube and an atom in a center of the cube. Each corner atom is often a corner of a cube of another BCC unit cell, such that each corner atom may be shared among eight BCC unit cells. Exemplary BCC metals include tungsten, molybdenum, niobium, tantalum, vanadium (V), chromium (Cr), and iron (Fe). When refractory metal alloy targets are positioned in PVD chamber 10 for PVD processing, target material sputtered from target 25 (such as refractory metal atoms and BCC metal atoms) form material layer 20, and material layer 20 is a refractory metal-based layer that includes the refractory metal and the BCC metal. A Young's modulus of the refractory metal-based layer is lower than a Young's modulus of the refractory metal. In some embodiments, where a reactive gas is introduced into PVD chamber 10 during PVD processing, the refractory metal-based layer can include elements from the reactive gas. For example, where nitrogen-containing gas is introduced into the PVD chamber 10, the refractory metal-based layer can the refractory metal, the BCC metal, and nitrogen.

In some embodiments, target 25 is a tungsten alloy target that includes tungsten alloyed with a BCC metal, and material layer 20 is a tungsten-based alloy layer that includes tungsten and the BCC metal. Since tungsten is a BCC metal, other BCC metals are generally completely miscible with tungsten, such that alloying BCC metals with tungsten forms a solid solution without intermetallic phases. A Young's modulus of the BCC metal is lower than a Young's modulus of tungsten (which is about 411 gigapascals (GPa)). For example, tungsten is alloyed with niobium (having a Young's modulus of about 105 GPa), tantalum (having a Young's modulus of about 186 GPa), vanadium (having a Young's modulus of about 128 GPa), or a combination thereof. Any tungsten alloy target and/or tungsten-based alloy layer will exhibit a Young's modulus less than tungsten (for example, less than about 411 GPa). Given that niobium and tungsten have a same lattice parameter (for example, 3.30 Å), niobium is particularly well suited for alloying with tungsten. Alloying tungsten with a BCC metal (such as niobium, tantalum, or vanadium) forms a tungsten alloy that is softener than pure tungsten by significantly reducing Young's modulus. Accordingly, any tungsten-based alloy layer fabricated from the tungsten alloy targets described herein exhibits a significantly reduced Young's modulus (as compared to a pure tungsten layer), eliminating (or significantly reducing) flaking of particles from shield 60 during PVD processing.

In some embodiments, target 25 is a molybdenum alloy target that includes molybdenum alloyed with a BCC metal, and material layer 20 is a molybdenum-based alloy layer that includes molybdenum and the BCC metal. Since molybdenum is a BCC metal, other BCC metals are generally completely miscible with molybdenum, such that alloying BCC metals with molybdenum forms a solid solution without intermetallic phases. A Young's modulus of the BCC metal is lower than a Young's modulus of molybdenum (which is about 329 GPa). For example, molybdenum is alloyed with niobium (having a Young's modulus of about 105 GPa), tantalum (having a Young's modulus of about 186 GPa), vanadium (having a Young's modulus of about 128 GPa), or a combination thereof. Given that niobium has a lattice parameter (for example, 3.15 Å) close to a lattice parameter of molybdenum (for example, 3.30 Å), niobium is particularly well suited for alloying with molybdenum. Any molybdenum alloy target and/or molybdenum-based alloy layer will exhibit a Young's modulus less than molybdenum (for example, less than about 329 GPa). Alloying molybdenum with a BCC metal (such as niobium, tantalum, or vanadium) forms a molybdenum alloy that is softener than pure molybdenum by significantly reducing Young's modulus. Accordingly, any molybdenum-based alloy layer fabricated from the molybdenum alloy targets described herein exhibits a significantly reduced Young's modulus (as compared to a pure molybdenum layer), eliminating (or significantly reducing) flaking of particles from shield 60 during PVD processing.

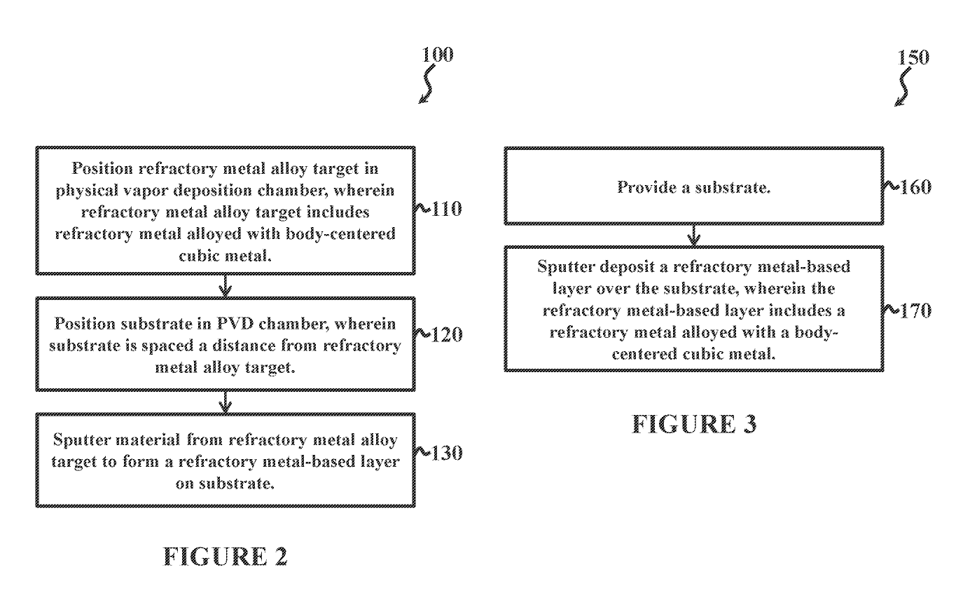

FIG. 2 illustrates a flow chart of an exemplary method 100 for reducing particles in a physical vapor deposition (PVD) chamber according to various aspects of the present disclosure. Method 100 begins at block 110, where a refractory metal alloy target (for example target 25) is positioned in a physical vapor deposition chamber (for example, PVD chamber 10). Refractory metal alloy target includes a refractory metal (for example, tungsten or molybdenum) alloyed with a body-centered cubic (BCC) metal (for example, niobium, tantalum, vanadium, or a combination thereof). The BCC metal has a Young's modulus lower than a Young's modulus of the refractory metal. At block 120, a substrate (for example, substrate 15) is positioned in the PVD chamber, where the substrate is spaced a distance from the refractory metal alloy target. At block 130, material is sputtered from the refractory metal alloy target to form a refractory metal-based layer (for example, a tungsten-based alloy layer or a molybdenum-based alloy layer) over the substrate. The refractory metal-based layer has a Young's modulus lower than a Young's modulus of the refractory metal, such that any refractory metal-based layer adhering to shield 60 or elsewhere in PVD chamber is less susceptible to flaking during PVD processing.

Refractory metal-based layers achieved using refractory metal alloy targets during PVD processing described herein can be implemented in various integrated circuit applications. FIG. 3 illustrates a flow chart of a method 150 for manufacturing an integrated circuit device according to various aspects of the present disclosure. Method 150 begins at block 160, where a substrate (for example, substrate 15) is provided. At block 170, a refractory metal-based layer (for example, a tungsten-based alloy layer or a molybdenum-based alloy layer) is sputter deposited over the substrate. The refractory metal-based layer includes a refractory metal alloyed with a body-centered cubic (BCC) metal (for example, niobium, tantalum, vanadium, or a combination thereof). In various embodiments, the refractory metal-based layer has a Young's modulus lower than a Young's modulus of the refractory metal. Subsequent processing may be performed with the substrate to manufacture various integrated circuit features and/or integrated circuit structures of the integrated circuit device.

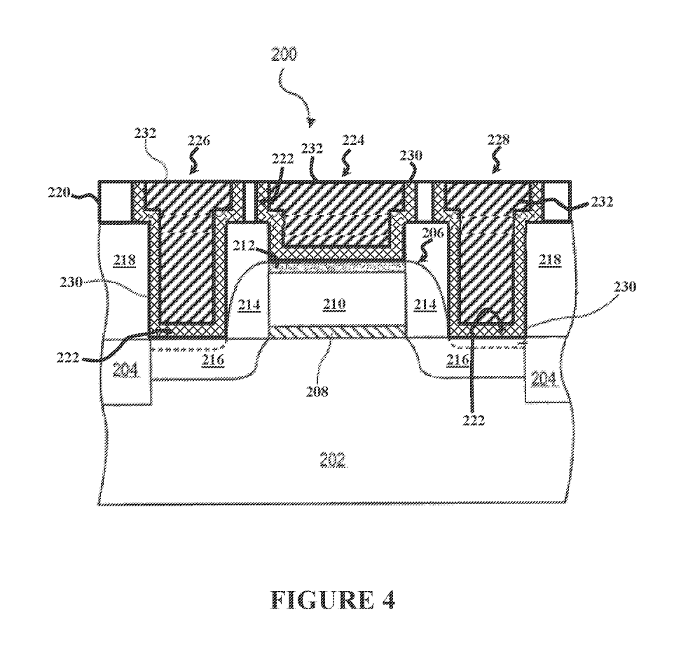

Refractory metal-based layers (which include a refractory metal alloyed with a BCC metal) disclosed herein can be implemented in integrated circuit devices. FIG. 4 illustrates a cross-sectional view of an exemplary integrated circuit device 200 according to various aspects of the present disclosure. Integrated circuit device 200 includes one or more electronic components, such as transistors, resistors, capacitors, diodes, power sources, inductors, sensors, transceivers, receivers, antennas, other electronic components, or a combination thereof. Electronic components associated with integrated circuit device 200 may include those that are mounted on integrated circuit device 200 or those connected to integrated circuit device 200. Integrated circuit device 200 may be used in a number of applications, such as microprocessors, optoelectronics, logic blocks, audio amplifiers, and/or any other suitable application, depending on the electronic components associated with integrated circuit device 200. In some implementations, integrated circuit device 200 may be employed as part of a chipset for executing one or more related functions in a computer.

In FIG. 4, integrated circuit device 200 includes a transistor fabricated on a substrate 202, such as metal-oxide-semiconductor field-effect transistor (MOSFET). Isolation regions 204, such as shallow trench isolations (STIs) or deep trench isolations (DTIs), formed in substrate 202 isolate electronic components (such as the transistor) of integrated circuit device 200. In various implementations, the transistor is a planar transistor, non-planar transistor, or a combination thereof. Non-planar transistor includes a fin-like FET (FinFET), such as a double-gate transistor or a tri-gate transistor, along with a wrap-around or an all-around gate transistor, such as a nanoribbon or a nanowire transistor. Substrate 202 includes any suitable semiconductor material, such as silicon, germanium, indium antimonide, lead telluride, indium arsenide, indium phosphide, gallium arsenide, indium gallium arsenide, gallium antimonide, other group III-V materials, other group IV materials, other suitable semiconductor materials, or combinations thereof. In some embodiments, substrate 202 can implement silicon-on-insulator (SOI) or silicon-on-sapphire (SOS) technology.

The transistor includes a gate stack 206 including at least two material layers, such as a gate dielectric layer 208 and a gate electrode layer 210. Gate dielectric layer 208 is formed on substrate 202, and gate electrode layer 210 is formed on gate dielectric layer 208. In the depicted embodiment, gate stack 206 further includes a gate silicide layer 212 formed on gate electrode layer 210. Gate dielectric layer 208 includes a dielectric material, such as silicon oxide, silicon dioxide (SiO₂), a high-k dielectric material, or a combination thereof. Exemplary high-k dielectric materials include hafnium oxide, hafnium silicon oxide, hafnium silicon oxynitride, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, other high-k dielectric material, or combinations thereof. In some embodiments, gate dielectric layer 208 includes more than one gate dielectric layer, such as an interface layer (for example, a SiO₂ layer) formed on substrate 202 and a high-k dielectric layer formed on the interface layer. Gate electrode layer 210 includes a conductive material, such as polysilicion, a P-type work function metal, an N-type work function metal, or combinations thereof. For a p-type MOS (PMOS) transistor, gate electrode layer 210 includes a p-type work function metal, such as ruthenium, palladium, platinum, cobalt, nickel, conductive metal oxides thereof (for example, ruthenium oxide), metal alloys thereof, other p-type work function metal, or combinations thereof. In some embodiments, the PMOS transistor will include a PMOS gate electrode having a work function between about 4.9 eV and about 5.2 eV. For an n-type MOS (NMOS) transistor, gate electrode layer 210 includes an n-type work function metal, such as hafnium, zirconium, titanium, tantalum, aluminum, hafnium carbide, zirconium carbide, titanium carbide, tantalum carbide, aluminum carbide, metal alloys thereof, other n-type work function metal, or combinations thereof. In some embodiments, the NMOS transistor will include a NMOS gate electrode having a work function between about 3.9 eV and about 4.2 eV. In some embodiments, gate electrode layer 210 includes at least two metal layers, for example, a work function metal layer and a metal fill layer. Gate electrode layer 210 can include further metal layers, such as barrier layers. Gate silicide layer 212 includes any metal capable of reacting with silicon (such as titanium, tantalum, tungsten, cobalt, nickel, platinum, palladium, other suitable metal, metal alloys thereof, or combinations thereof) to form a metal silicide, which can enhance electrical contact to gate stack 206.

When viewing transistor along the source-channel-drain direction, gate dielectric layer 208 and gate electrode layer 210 as depicted have planar, non-U-shaped structures. Both gate dielectric layer 208 and gate electrode layer 210 include planar layers that extend substantially parallel to a top surface of substrate 202 (on which gate stack 206 is disposed) and do not include sidewall portions substantially perpendicular to the top surface of substrate 202. In some implementations, when viewing a cross-section of the transistor along the source-channel-drain direction, gate dielectric layer 208 and/or gate electrode layer 210 have U-shaped structures that include a bottom portion that is substantially parallel to the top surface of substrate 202 and two sidewall portions that are substantially perpendicular to the top surface of substrate 202. For example, in some embodiments, gate dielectric layer 208 and gate electrode layer 210 have U-shaped structures, where gate dielectric layer 208 includes a bottom portion that lines the top surface of substrate 202 and two sidewall portions that gate stack 206 and gate electrode layer 210 fills the U-shaped structure of gate dielectric layer 208. In some implementations, at least one conductive layer of the gate electrode layer 208 is a non-U shaped structure (such as a planar layer). In some implementations, gate dielectric layer 208 and/or gate electrode layer 210 have a combination of U-shaped structures and non-U-shaped structures. For example, in some embodiments, gate dielectric layer 208 has a non-U shaped structure and gate electrode layer 210 has a U-shaped structure, where gate electrode layer 210 includes one or more U-shaped conductive layers formed on planar gate dielectric layer 208.

The transistor further includes gate spacers 214 disposed on sidewalls of gate stack 206. In some implementations, gate spacers 214 may be formed to bracket gate stack 206. Gate spacers 214 include any suitable material, such as silicon nitride, silicon oxide, silicon carbide, silicon oxynitride, or a combination thereof. In some embodiments, gate spacers 214 include silicon nitride doped with carbon. Gate spacers 214 can include a plurality of spacer pairs, for example, two pairs, three pairs, or four pairs of sidewall spacers formed on opposing sides of gate stack 206. The transistor further includes source/drain regions 216 formed in substrate 202 adjacent gate stack 206, where gate stack 206 is disposed on substrate 202 between a source region and a drain region (collectively referred to as source/drain regions 216). Source/drain regions 216 are generally formed using an implantation/diffusion process or an etching/deposition process. In the implantation/diffusion process, an ion implantation process can implant dopants (such as boron, aluminum, antimony, phosphorous, arsenic, or other suitable dopant) into substrate 202 to form source/drain regions 216. An annealing process may be performed to activate the dopants, causing the dopants to diffuse further into substrate 202. In the etching/deposition process, substrate 202 may be etched to form recesses at desired locations for source/drain regions 216, and then an epitaxial deposition process may be performed to fill the recesses with a suitable material for source/drain regions 216. In some implementations, the source/drain regions 216 are formed by epitaxially depositing a silicon alloy, such as silicon germanium or silicon carbide. In some embodiments, the epitaxially deposited silicon alloy may be doped in situ with any suitable dopants (such as boron, arsenic, or phosphorous). In some implementations, source/drain regions 216 can be formed from alternate semiconductor materials, such as germanium or a group III-V material. In some implementations, one or more layers of metal and/or metal alloys may be used to form source/drain regions 216.

An interconnect structure is formed over substrate 202. Interconnect structure includes various interconnects for connecting various electronic components, such as the transistor, of integrated circuit device 200. The interconnect structure can include various interlayer dielectric (ILD) layers, such as an ILD layer 218 and an ILD layer 220. ILD layers 218 and 220 include any suitable dielectric material, such as a low-k dielectric material. Exemplary low-k dielectric materials include silicon dioxide, carbon doped oxide, silicon nitride, organic polymers (such as perfluorocyclobutane or polytetrafluoroethylene), fluorosilicate glass (FSG), organosilicates (such as silsesquioxane, siloxane, or organosilicate glass), other low-k dielectric material, or combinations thereof ILD layers 218 and 220 can include pores or air gaps to reduce their dielectric constant. Various metallization layers formed in ILD layers 218 and 220 can form contacts to the transistor, for example, to gate stack 206 and source/drain regions 216. For example, openings 222 formed in ILD layers 218 and 220 expose gate stack 206 and source/drain regions 216, where an interconnect 224 is formed to gate stack 206 and interconnect 226 and interconnect 228 are formed to source/drain regions 216. Interconnect 224, interconnect 226, and interconnects 228 each include a barrier layer 230 and a conductive interconnect layer 232. Barrier layer 230 includes a material that can serve as both a diffusion barrier for a material of conductive interconnect layer 232 (such as acting as a diffusion barrier to copper or copper alloys forming conductive interconnect layer 232), such as titanium, tantalum, titanium nitride, tantalum nitride, tungsten, molybdenum, ruthenium, paladium, rhodium, nickel, cobalt, platinum, other suitable material, metal alloys thereof, or combinations thereof. Conductive interconnect layer 232 includes any suitable conductive material for forming interconnects in an interconnect structure, including copper, aluminum, tungsten, cobalt, ruthenium, nickel, iron, molybdenum, other suitable conductive material, metal alloys thereof, or combinations thereof.

Various deposition, patterning, and/or etching processes are performed to form isolation regions 204, gate stack 206 (including gate dielectric layer 208, gate electrode layer 210, and gate silicide layer 212), gate spacers 214, source/drain regions 216, and the interconnect structure (including ILD layers 218 and 220 and interconnects 224, 226, and 228 (including barrier layer 230 and conductive interconnect layer 232)). Depositions processes can include physical vapor deposition processes, chemical vapor deposition processes, atomic layer deposition processes, electrodeposition processes (such as electroplating and/or electroless plating), epitaxial processes, thermal oxidation processes, other suitable deposition processes, or a combination thereof. Patterning processes include any process used to pattern a material layer. Various patterning processes can include forming a photoresist layer and/or hard mask layer over substrate 202 (for example, by a spin coating process) and performing a lithography process to pattern the photoresist layer and/or hard mask layer. The lithography process can include optical photolithography, immersion photolithography, deep ultraviolet (UV) lithography, extreme UV lithography, other suitable lithography process, or a combination thereof. Etching processes can include dry etching processes, wet etching processes, other suitable etching processes, or a combination thereof. Forming the various features of integrated circuit device 200 can further include performing annealing processes and/or any other suitable process.

As noted, refractory metal-based layers (which include a refractory metal alloyed with a BCC metal) disclosed herein can be implemented in integrated circuit device 200. In some embodiments, various features of the transistor of integrated circuit device 200, such as gate stack 206, can include refractory metal-based layers. For example, in some embodiments, gate stack 206 includes a barrier layer that is a refractory metal-based layer. In some embodiments, a gate electrode, such as gate electrode layer 208, of the transistor includes a refractory metal-based layer. In some embodiments, various features of the interconnect structure can include refractory metal-based layers. For example, interconnect 224, interconnect 226, and/or interconnect 228 can implement a refractory metal-based layer in barrier layer 230 and/or conductive interconnect layer 232. In some embodiments, barrier layer 230 and/or conductive interconnect layer 232 is a refractory metal-based layer. Various other electronic components of integrated circuit device 200 can implement refractory metal-based layers. For example, a capacitor of integrated circuit device 200 can have an electrode that is a refractory metal-based layer. Furthermore, refractory metal-based layers may be used in fabricating integrated circuit device 200. For example, in some embodiments, a refractory metal-based layer serves as a hard mask layer during processing of integrated circuit device 200.

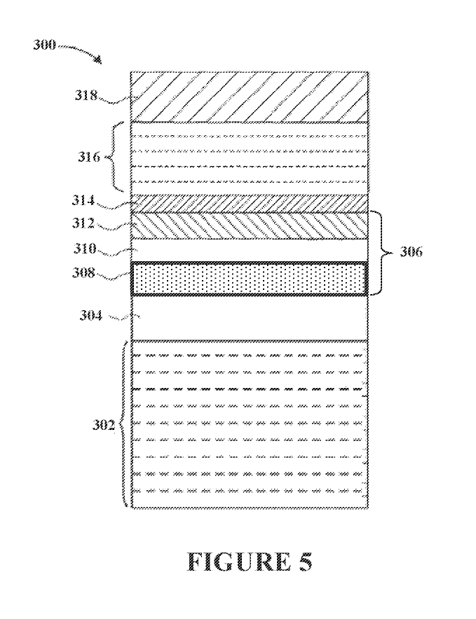

Refractory metal-based layers (which include a refractory metal alloyed with a BCC metal) disclosed herein can also be implemented in spin-transfer torque magnetic random-access memory (STT-MRAM) devices. STT-MRAM is a non-volatile memory device that utilizes a phenomenon known as tunneling magnetoresistance (TMR). FIG. 5 illustrates a cross-sectional view of an exemplary material layer stack 300 that can be implemented in a STT-MRAM device according to various aspects of the present disclosure. Material layer stack 300 may be formed over any suitable substrate (not shown), and generally includes an electrode 302, a pinned layer 304, a magnetic tunnel junction (MTJ) structure 306 (which includes a fixed magnetic layer 308, a tunneling layer 310, and a free magnetic layer 312), a crystallization barrier layer 314, a magnetic anisotropy enhancing layer (AEL) 316, and an electrode 318. In some embodiments, an order of the material layers in material layer stack 300 may be modified depending on a desired configuration for a STT-MRAM device. Material layer stack 300 is fabricated using any suitable processing, including the various processes described herein (including, but not limited to, PVD processes (such as the PVD processes described herein), annealing processes, lithography processes, etching processes, planarization processes (such as chemical mechanical polishing processes), or other suitable processes).

Electrode 302 includes any material or stack of materials suitable for electrically contacting a fixed magnetic layer side of a STTM device, and electrode 318 includes any material or stack of materials suitable for electrically contacting a free magnetic layer side of the STTM device. Exemplary materials include ruthenium, tantalum, copper, aluminum, gold, other suitable material, or combinations thereof. For example, in some embodiments, electrode 302 can include alternating layers of a first metal and a second metal, such as alternating ruthenium layers and tantalum layers, and electrode 318 can include a ruthenium layer. In some embodiments, electrode 318 includes a conductive material that can prevent oxygen from migrating into MTJ structure 306.

Pinned layer 304 includes a material or stack of materials suitable to facilitate pinning fixed magnetic layer 308 (in other words, locking spins in an adjacent fixed magnetic layer, such as fixed magnetic layer 308). For example, in some embodiments, pinned layer 304 includes alternating cobalt layers and platinum layers to form a multilayer stack. MTJ structure 306 is configured as a perpendicular, anisotropic epitaxial MTJ structure in the depicted embodiment, though the present disclosure contemplates other configurations. Fixed magnetic layer 308 (also referred to as a ferromagnetic layer) includes any material or stack of materials suitable for maintaining a fixed magnetization direction (for example, a fixed majority spin). In some embodiments, fixed magnetic layer 308 includes a single cobalt iron boride (CoFeB) layer. In some embodiments, fixed magnetic layer 308 includes a stack of layers, such as a CoFeB layer disposed on pinned layer 304, a ruthenium layer disposed on the CoFeB layer, and a CoFe layer disposed on the ruthenium layer. Tunneling layer 310 (also referred to as a spin filter layer) includes any material or stack of materials suitable for allowing current of a majority spin to pass through tunneling layer 310, while impeding to some extent current of a minority spin from passing through (in other words, a spin filter) tunneling layer 310. Such can enhance tunneling magneto-resistance of MTJ structure 306. For example, in some embodiments, tunneling layer 310 includes magnesium oxide (MgO) or aluminum oxide (Al₂O₃). Free magnetic layer 312 (also referred to as a memory layer or a ferromagnetic layer) includes any material or stack of materials suitable for transitioning between magnetization directions (for example, between a majority spin and a minority spin), such that magnetization direction can easily rotate to a parallel state and an antiparallel state with respect to fixed magnetic layer 308. For example, in some embodiments, free magnetic layer 312 includes a cobalt iron (CoFe), a cobalt iron boride (CoFeB) layer, or a combination thereof.

Crystallization barrier layer 314 includes any material or stack of materials suitable for providing magnetic coupling (direct or indirect) between free magnetic layer 312 and magnetic AEL 316 to achieve perpendicular magnetic anisotropy within free magnetic layer 312. For example, in some embodiments, crystallization barrier layer 314 can include a material that offers suitable solubility of boron and/or offers a low boron alloy temperature, to advantageously absorb boron during processing (such as during a post-deposition anneal) and reduce any boron at an interface between free magnetic layer 312 and tunneling layer 310 (for example, an interface between a CoFeB layer and a MgO layer). In some embodiments, crystallization barrier layer 314 is multi-layered. Exemplary materials for crystallization barrier layer 314 include tantalum, ruthenium, tungsten, vanadium, molybdenum, niobium, chromium, other suitable metal, metal alloys thereof, or combinations thereof. In various embodiments, crystallization barrier layer 314 is a refractory metal-based layer, such as a tungsten-based alloy layer or a molybdenum-based alloy layer, as described herein.

Magnetic AEL 316 includes any material or stack of materials suitable for coupling to free magnetic layer 312. In various embodiments, magnetic AEL 316 is configured to promote out-of-plane alignment within free magnetic layer 312. For example, in some embodiments, magnetic AEL 316 promotes out-of-plane alignment within an iron-rich CoFeB layer of free magnetic layer 312. In some embodiments, magnetic AEL 316 is multi-layered, for example, including multiple bilayers that include a magnetic material layer and a non-magnetic layer. The magnetic layer can include a ferromagnetic material, such as cobalt, nickel, iron, other suitable ferromagnetic material, metal alloys thereof, or combinations thereof. The non-magnetic layer can include a non-magnetic material, such as palladium, platinum, ruthenium, gold, iridium, other suitable non-magnetic material, or combinations thereof.

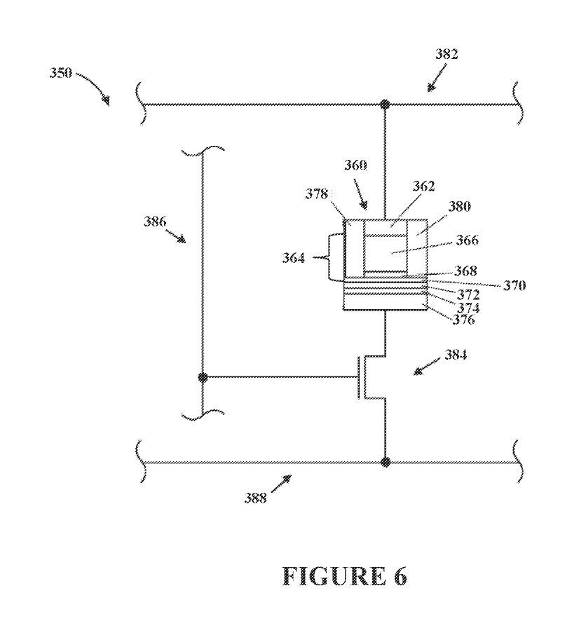

FIG. 6 illustrates a schematic diagram of an exemplary spin transfer torque (STT) memory bit cell 350 according to various aspects of the present disclosure. STT memory bit cell 350 includes a STT element 360 having: a fixed magnetic layer electrode 362; a magnetic tunneling junction (MTJ) structure 364 (which includes a fixed magnetic layer 366, a tunneling layer 368, and a free magnetic layer 370); a crystallization barrier layer 372, a magnetic anisotropy enhancement layer 374, and a free magnetic layer electrode 376. Tunneling layer 368 is disposed between fixed magnetic layer 366 and free magnetic layer 370. In the depicted embodiment, crystallization barrier layer 372 and magnetic anisotropy enhancement layer 374 are disposed between MTJ structure 364 and free magnetic layer electrode 376. In some embodiments, a material layer stack of STT element 360 may be configured as material layer stack 300 described with reference to FIG. 5. In some embodiments, portions of STT element 360 are disposed between dielectric layers. For example, in the depicted embodiment, fixed magnetic layer electrode 362, fixed magnetic layer 366, and tunneling layer 368 are disposed between a dielectric layer 378 and a dielectric layer 380. STT memory bit cell 350 further includes a bit line 382, a transistor 384, a word line 386, and a source line 388. Fixed magnetic layer electrode 362 is electrically connected to bit line 382, and free magnetic layer electrode 376 is electrically connected to transistor 384. Transistor 384 is electrically connected to word line 386 and source line 388 in any manner suitable to achieve desired operation of STT memory bit cell 350. STT memory bit cell 350 can further include additional read and write circuitry (not shown), a sense amplifier (not shown), a bit line reference (not shown), and/or any other suitable STT memory bit features to achieve desired operation of STT memory bit cell 350. In some embodiments, a plurality of STT memory bit cells 350 may be operably connected to one another to form a memory array (not shown) that can be incorporated into a non-volatile memory device.

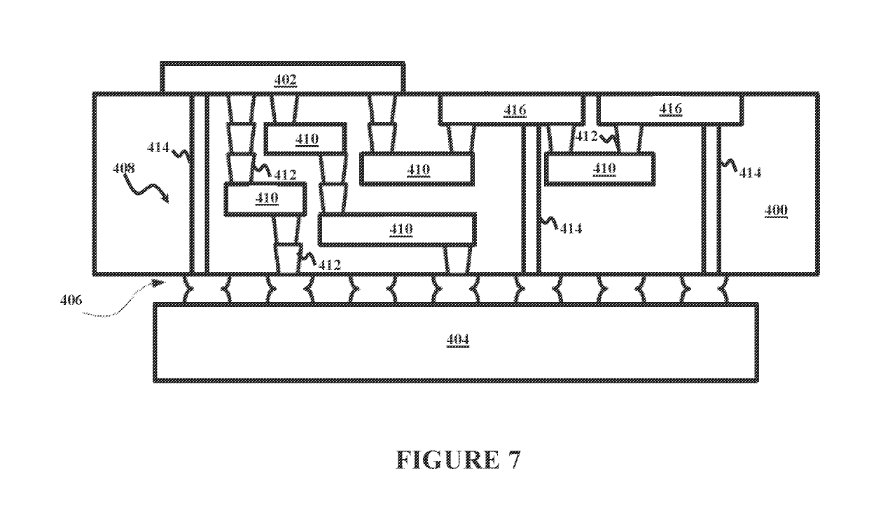

FIG. 7 illustrates a cross-sectional view of an exemplary interposer 400 according to various aspects of the present disclosure. Interposer 400 is an intervening substrate used to bridge a first substrate 402 to a second substrate 404. In some embodiments, first substrate 402 is an integrated circuit die, and second substrate 404 is another integrated circuit die, a memory module, or a computer motherboard. Generally, interposer 400 serves as an electrical interface routing between first substrate 402 and second substrate 404. For example, interposer 400 can spread a connection to a wider pitch or reroute a connection to a different connection. In some embodiments, interposer 400 couples first substrate 402 (for example, an integrated circuit die) to a ball grid array (BGA) 406 that is coupled to second substrate 404. In some embodiments, as depicted, first substrate 402 and second substrate 404 are attached to opposing sides of interposer 400. In some embodiments, first substrate 402 and second substrate 404 are attached to the same side of interposer 400. In further embodiments, three or more substrates may be interconnected by way of interposer 400.

Interposer 400 may be formed of an epoxy resin, a fiberglass-reinforced epoxy resin, a ceramic material, a polymer material (such as polyimide), or any other suitable material. In some embodiments, interposer 400 is formed of alternate rigid or flexible materials that may include the same materials described above for use in a semiconductor substrate, such as silicon, germanium, group III-V materials, group IV materials, or combinations thereof. Interposer 400 can include an interconnect structure 408 that includes metal interconnects, including but not limited to, trenches 410, vias 412, and through-silicon vias (TSVs) 414. Interconnect structure 408 can implement refractory metal-based layers (which include a refractory metal alloyed with a BCC metal) disclosed herein in trenches 410, vias 412, and/or TSVs 414. For example, in some embodiments, a barrier layer configured as a refractory metal-based layer can be implemented in trenches 410, vias 412, and/or TSVs 414. Interposer 400 can also include embedded devices 416, including both passive devices and active devices. Exemplary embedded devices include capacitors, decoupling capacitors, resistors, inductors, fuses, diodes, transformers, sensors, electrostatic discharge (ESD) devices, other suitable embedded devices, or combinations thereof. In some embodiments, RF devices, power amplifiers, power management devices, antennas, arrays, sensors, microelectromechanical systems (MEMS) devices, other devices, or combinations thereof can be formed on interposer 400.

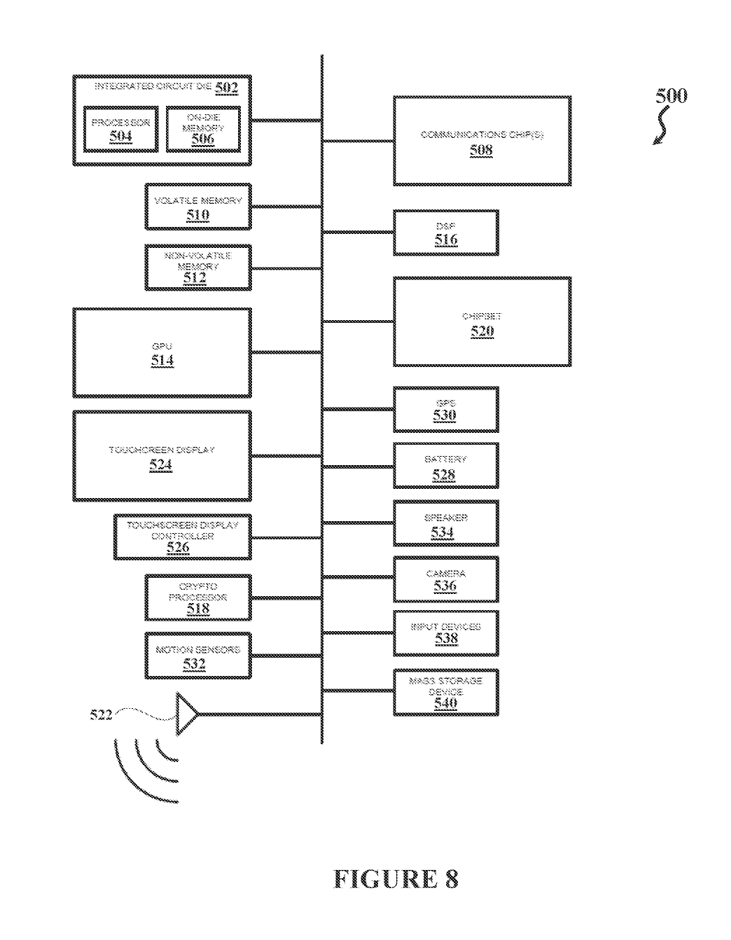

FIG. 8 illustrates a schematic block diagram of an exemplary computing device 500 according to various aspects of the present disclosure. Computing device 500 includes a number of components. In some implementations, these components are attached to one or more motherboards. In some implementations, some or all of these components are fabricated onto a system-on-a-chip (SoC) die. The various components of computing device 500 can implement refractory metal-based layers as described herein. In FIG. 8, computing device 500 includes an integrated circuit die 502 (which can include a processor 504 and a memory 506 (such as an on-chip memory)) and a communications chip 508. In some embodiments, integrated circuit die 502 physically and electrically couples to a motherboard. In some embodiments communications chip 508 also physically and electrically couples to the motherboard. In some embodiments, communications chip 508 is part of integrated circuit die 502 and/or processor 504. The term “processor” may refer to any device or portion of a device that processes electronic data from registers and/or memory to transform that electronic data into other electronic data that may be stored in registers and/or memory. Memory 506, often used as cache memory, can be provided by any suitable memory technology, such as embedded DRAM (eDRAM) or spin-transfer torque memory (STTM or STT-MRAM).

Communications chip 508 (also referred to as a communications logic unit) enables wireless communications for data transfer to and from computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communications chip 508 may implement any of a number of wireless standards or protocols, including, but not limited to, Wi-Fi (IEEE 502.11 family), WiMAX (IEEE 502.16 family), IEEE 502.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Computing device 500 may include multiple communications chips 508. For example, a first communications chip may be dedicated to shorter range wireless communications, such as Wi-Fi and Bluetooth, and a second communications chip may be dedicated to longer range wireless communications, such as GPS, EDGE, GPRS, CDMA, WiMAX, LTE, Ev-DO, and others.

Depending on its applications, computing device 500 may include other components that may or may not be physically and/or electrically coupled to the motherboard or fabricated within an SoC die. These other components include, but are not limited to, a volatile memory 510 (for example, dynamic random access memory (DRAM)), a non-volatile memory 512 (for example, read only memory (ROM) or flash memory), a graphics processing unit (GPU) 514, a digital signal processor (DSP) 516, a crypto processor 518 (a specialized processor that can execute cryptographic algorithms within hardware), a chipset 520, an antenna 522, a display 524 (such as a touchscreen display), a display controller 526 (such as a touchscreen display controller), a power source (for example, a battery 528), a power amplifier (not shown), a voltage regulator (not shown), a video codec (not shown), an audio codec (not shown), a global positioning system (GPS) device 530, motion sensor(s) 532 (which may include a motion processor, an accelerometer, a gyroscope, and/or a compass), a speaker 534, a camera 536, input devices 538 (such as a keyboard, mouse, stylus, and touchpad), and a mass storage device 540 (such as a hard disk drive, a compact disk (CD), a digital versatile disk (DVD), and so forth). In some embodiments, memory 506 and/or memory 512 can implement features of the STT-MRAM described above with references to FIG. 5 and FIG. 6. In some embodiments, various components of computing device 500 can implement features of the integrated circuit device described above with reference to FIG. 4.

In various implementations, computing device 500 may be a laptop computer, a netbook computer, a notebook computer, an ultrabook computer, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, computing device 500 may be any other electronic device that processes data.

OVERVIEW OF EXAMPLE EMBODIMENTS: Various embodiments of the present disclosure include physical vapor deposition (PVD) targets, refractory metal-based layers for integrated circuit devices and/or non-volatile memory devices, methods for reducing particles in during PVD processing, and/or methods for manufacturing integrated circuit devices and/or non-volatile memory devices, as described below.

In some embodiments, an exemplary method for reducing particles in a PVD chamber includes positioning a refractory metal alloy target in the PVD chamber, positioning a substrate in the PVD chamber a distance from the refractory metal alloy target, and sputtering material from the refractory metal alloy target to form a refractory metal-based layer over the substrate. The refractory metal alloy target includes a refractory metal alloyed with a body-centered cubic (BCC) metal. In some embodiments, the BCC metal has a Young's modulus lower than a Young's modulus of the refractory metal.

In some embodiments, the refractory metal alloy target is a tungsten alloy target that includes tungsten alloyed with the BCC metal, and the refractory metal-based layer is a tungsten-based alloy layer that includes tungsten and the BCC metal. In some embodiments, the BCC metal has a Young's modulus lower than a Young's modulus of tungsten. In some embodiments, the BCC metal is niobium, tantalum, vanadium, or a combination thereof. In some embodiments, tungsten-based alloy layer further includes nitrogen.

In some embodiments, the refractory metal alloy target is a molybdenum alloy target that includes molybdenum alloyed with the BCC metal, and the refractory metal-based layer is a molybdenum-based alloy layer that includes molybdenum and the BCC metal. In some embodiments, the BCC metal has a Young's modulus lower than a Young's modulus of molybdenum. In some embodiments, the BCC metal is niobium, tantalum, vanadium, or a combination thereof. In some embodiments, molybdenum-based layer further includes nitrogen.

In some embodiments, sputtering material from the refractory metal alloy target to form the refractory metal-based layer includes supplying an inert gas into the PVD chamber. In some embodiments, sputtering material from the refractory metal alloy target to form the refractory metal-based layer includes supplying a reactive gas, such as nitrogen, into the PVD chamber. In some embodiments, sputtering material from the refractory metal alloy target to form the refractory metal-based layer includes biasing the target.

In some embodiments, an exemplary PVD target includes a refractory metal alloyed with a BCC metal, wherein the BCC metal has a Young's modulus lower than a Young's modulus of the refractory metal. In some embodiments, the refractory metal is molybdenum, and the BCC metal is niobium, tantalum, vanadium, or a combination thereof. In some embodiments, the refractory metal is tungsten, and the BCC metal is niobium, tantalum, vanadium, or a combination thereof.

In some embodiments, an exemplary integrated circuit device includes a substrate and a refractory metal-based layer disposed over the substrate, wherein the refractory metal-based layer includes a refractory metal alloyed with a BCC metal. In some embodiments, the BCC metal has a Young's modulus lower than a Young's modulus of the refractory metal. In some embodiments, the refractory metal is tungsten. In some embodiments, the refractory metal is molybdenum. In some embodiments, the BCC metal is niobium, tantalum, vanadium, or a combination thereof. In some embodiments, the refractory metal-based layer, such as a tungsten alloy layer or a molybdenum alloy layer, further includes nitrogen.

In some embodiments, the integrated circuit device includes a transistor, and the refractory metal-based metal layer forms a gate electrode of the transistor. In some embodiments, the integrated circuit device includes a transistor, and the refractory metal-based metal layer forms a barrier layer of the transistor. In some embodiments, the integrated circuit includes an interconnect structure disposed over the substrate, and the refractory metal-based layer forms a barrier layer included in the interconnect structure. In some embodiments, the integrated circuit device includes a capacitor, and the refractory metal-based layer forms an electrode of the capacitor.

In some embodiments, an exemplary method for manufacturing an integrated circuit device includes providing a substrate and sputter depositing a refractory metal-based layer over the substrate. The refractory metal-based layer includes a refractory metal alloyed with a BCC metal. In some embodiments, the BCC metal has a Young's modulus lower than a Young's modulus of the refractory metal. In some embodiments, the refractory metal is tungsten. In some embodiments, the refractory metal is molybdenum. In some embodiments, the BCC metal is niobium, tantalum, vanadium, or a combination thereof. In some embodiments, sputter depositing the refractory metal-based layer over the substrate includes forming a hard mask layer. In some embodiments, sputter depositing the refractory metal-based layer over the substrate includes forming a barrier layer for an integrated circuit structure. In some embodiments, sputter depositing the refractory metal-based layer over the substrate includes forming an electrode layer for an electronic component, such as a transistor and/or a capacitor of the integrated circuit structure.

In some embodiments, an exemplary spin-transfer torque magnetic random-access memory (STT-MRAM) device includes a magnetic tunneling junction (MTJ) structure that includes a fixed magnetic layer, a free magnetic layer, and a tunneling layer disposed between the fixed magnetic layer and the free magnetic layer. The STT-MRAM device further includes a fixed magnetic layer electrode coupled to the fixed magnetic layer, and a free magnetic layer electrode coupled to the free magnetic layer. The STT-MRAM device further includes a crystallization barrier layer disposed between the free magnetic layer electrode and the free magnetic layer. The crystallization barrier layer is a refractory metal-based layer that includes a refractory metal alloyed with a BCC metal. In some embodiments, the BCC metal has a Young's modulus lower than a Young's modulus of the refractory metal. In some embodiments, the refractory metal is tungsten. In some embodiments, the refractory metal is molybdenum. In some embodiments, the BCC metal is niobium, tantalum, vanadium, or a combination thereof. In some embodiments, the refractory metal-based layer further includes nitrogen.

In some embodiments, an exemplary method for manufacturing a. STT-MRAM device includes forming a MTJ structure that includes a fixed magnetic layer, a free magnetic layer, and a tunneling layer disposed between the fixed magnetic layer and the free magnetic layer. The method further includes sputter depositing a crystallization barrier layer over the free magnetic layer, wherein the crystallization barrier layer is a refractory metal-based layer that includes a refractory metal alloyed with a body-centered cubic (BCC) metal. In some embodiments, the method further includes forming a fixed magnetic layer electrode coupled to the fixed magnetic layer, and forming a free magnetic layer electrode coupled to the free magnetic layer, where the crystallization barrier layer is disposed between the free magnetic layer electrode and the free magnetic layer. In some embodiments, the BCC metal has a Young's modulus lower than a Young's modulus of the refractory metal. In some embodiments, the refractory metal is tungsten. In some embodiments, the refractory metal is molybdenum. In some embodiments, the BCC metal is niobium, tantalum, vanadium, or a combination thereof. In some embodiments, the refractory metal-based layer further includes nitrogen.

1. A physical vapor deposition (PVD) target comprising:
a refractory metal alloyed with a body-centered cubic (BCC) metal, wherein the BCC metal has a Young's modulus lower than a Young's modulus of the refractory metal.

2. The PVD target of claim 1, wherein the refractory metal is molybdenum.

3. The PVD target of claim 1, wherein the refractory metal is tungsten.

4. The PVD target of claim 1, wherein the BCC metal is niobium, tantalum, vanadium, or a combination thereof.

5. A method for reducing particles in a physical vapor deposition (PVD) chamber, the method comprising:
positioning a refractory metal alloy target in the PVD chamber, wherein the refractory metal alloy target includes a refractory metal alloyed with a body-centered cubic (BCC) metal;
positioning a substrate in the PVD chamber, wherein the substrate is spaced a distance from the refractory metal alloy target; and
sputtering material from the refractory metal alloy target to form a refractory metal-based layer over the substrate.

6. The method of claim 5, wherein the BCC metal has a Young's modulus lower than a Young's modulus of the refractory metal.

7. The method of claim 5, wherein the refractory metal alloy target is a tungsten alloy target that includes tungsten alloyed with the BCC metal, and the refractory metal-based layer is a tungsten-based alloy layer that includes tungsten and the BCC metal.

8. The method of claim 7, wherein the BCC metal has a Young's modulus lower than a Young's modulus of tungsten.

9. The method of claim 5, wherein the refractory metal alloy target is a molybdenum alloy target that includes molybdenum alloyed with the BCC metal, and the refractory metal-based layer is a molybdenum-based alloy layer that includes molybdenum and the BCC metal.

10. The method of claim 9, wherein the BCC metal has a Young's modulus lower than a Young's modulus of molybdenum.

11. The method of claim 5, wherein the BCC metal is niobium, tantalum, vanadium, or a combination thereof.

12. The method of claim 5, wherein the refractory metal-based layer further includes nitrogen.

13. A spin-transfer torque magnetic random-access memory (STT-MRAM) device comprising:
a magnetic tunneling junction (MTJ) structure that includes a fixed magnetic layer, a free magnetic layer, and a tunneling layer disposed between the fixed magnetic layer and the free magnetic layer;
a fixed magnetic layer electrode coupled to the fixed magnetic layer;
a free magnetic layer electrode coupled to the free magnetic layer; and
a crystallization barrier layer disposed between the free magnetic layer electrode and the free magnetic layer, wherein the crystallization barrier layer is a refractory metal-based layer that includes a refractory metal alloyed with a body-centered cubic (BCC) metal.

14. The STT-MRAM device of claim 13, wherein the BCC metal has a Young's modulus lower than a Young's modulus of the refractory metal.

15. The STT-MRAM device of claim 13, wherein the refractory metal is tungsten.

16. The STT-MRAM device of claim 13, wherein the refractory metal is molybdenum.

17. The STT-MRAM device of claim 13, wherein the BCC metal is niobium, tantalum, vanadium, or a combination thereof.

18. The STT-MRAM device of claim 13, wherein the refractory metal-based layer further includes nitrogen.

19. A method for manufacturing a spin-transfer torque magnetic random-access memory (STT-MRAM) device, the method comprising:
forming a magnetic tunneling junction (MTJ) structure that includes a fixed magnetic layer, a free magnetic layer, and a tunneling layer disposed between the fixed magnetic layer and the free magnetic layer; and
sputter depositing a crystallization barrier layer over the free magnetic layer, wherein the crystallization barrier layer is a refractory metal-based layer that includes a refractory metal alloyed with a body-centered cubic (BCC) metal.

20. The method of claim 19, wherein the BCC metal has a Young's modulus lower than a Young's modulus of the refractory metal.

21. The method of claim 19, wherein the refractory metal is tungsten.

22. The method of claim 19, wherein the refractory metal is molybdenum.

23. The method of claim 19, wherein the BCC metal is niobium, tantalum, vanadium, or a combination thereof.

24. The method of claim 19, wherein the refractory metal-based layer further includes nitrogen.

25. The method of claim 19, further including:
forming a fixed magnetic layer electrode coupled to the fixed magnetic layer; and
forming a free magnetic layer electrode coupled to the free magnetic layer, wherein the crystallization barrier layer is disposed between the free magnetic layer electrode and the free magnetic layer.
